(19) United States
(12) Patent Application Publication
(10) Pub. No.: US 2025/0012882 A1
(43) Pub. Date: Jan. 9, 2025

(54) METHOD FOR ASCERTAINING AN OPTIMAL ENERGY-SAVING STATE OF A MAGNETIC RESONANCE IMAGING SYSTEM

(71) Applicant: Siemens Healthineers AG, Forchheim (DE)

(72) Inventors: Thomas Beck, Dormitz (DE); Swen Campagna, Engelthal (DE)

(21) Appl. No.: 18/764,327

(22) Filed: Jul. 4, 2024

(30) Foreign Application Priority Data
Jul. 4, 2023 (EP) 23183223.9

(51) Int. Cl. G01R 33/54; G05B 13/02

(52) U.S. Cl. CPC G01R 33/543; G05B 13/027

(57) ABSTRACT

A method for ascertaining an optimal energy-saving state of a magnetic resonance imaging system is provided. The method includes receiving a set of rules with a central controller, and receiving at least one state of at least one component with the central controller. The at least one component is a component of the magnetic resonance imaging system and/or an environment of the magnetic resonance imaging system. The set of rules includes at least one rule by which the optimal energy-saving state may be determined based on the at least one state of the at least one component. The method also includes determining the optimal energy-saving state based on the set of rules and the at least one state of the at least one component. The method also includes providing information regarding the optimal energy-saving state.

This application claims the benefit of European Patent Application No. EP 23183223.9, filed on Jul. 4, 2023, which is hereby incorporated by reference in its entirety.

### BACKGROUND

The present embodiments relate to ascertaining an optimal energy-saving state of a magnetic resonance imaging system and providing a trained function.

The energy consumption of a medical system is a major factor in the operating costs of the medical system. This applies, for example, to a magnetic resonance imaging (MRI) system. The energy consumption of an MRI system may be significantly reduced if the MRI system is set to an energy-saving state or standby state.

An MRI system may include a plurality of components (e.g., a gradient amplifier, a radio-frequency amplifier, a patient table, a helium compressor, a cooling system, a computing system, a generator for detuning currents, etc.). Individual components of the MRI system may include sub-components, such as, for example, a modulator, etc. An energy-saving state may be established by shutting down at least one component or sub-component of the MRI system or setting the at least one component or sub-component of the MRI system to a standby state. Herein, for example, a component may be set to different standby states from which the component may be activated again at different speeds.

Some components of an MRI system may be deactivated and reactivated again quickly. Deactivating a component may also provide deactivating a sub-component included by the component. Other components of an MRI system, such as, for example, the cooling system or the power supply, require a longer time to be shut down and, for example, reactivated. Thus, an MRI system may assume different energy-saving states in dependence on which components of the MRI system are shut down.

The energy-saving state assumed depends on how quickly the MRI system is to be ready for use again. For example, in regular operation between two patients, the MRI system may be ready for use again as soon as possible, so typically no component or only a component that may be activated quickly is shut down. For example, at night or at the weekend, the MRI system may be set to a “deeper” energy-saving state from which it takes longer for the MRI system to be ready for operation again. The more components of the MRI system that are shut down, the more energy may be saved, but the longer it may take for the MRI system to be ready for use again. Likewise, the time it takes for the MRI system to be ready for use again may depend on the type or depth of a standby state of a component.

It is known to set an MRI system to a specific energy-saving state on a time-controlled basis. Herein, the MRI system is set to specific energy-saving states at predefined times. For example, the MRI system may be set to the night state, a state from which it takes a long time until the MRI system is ready for operation again, at a specific time every evening.

The disadvantage of the time-controlled approach is that it is inflexible. Short-term unused times of the MRI system are not recognized, and the MRI system is not set to an energy-saving state in these cases. This provides that a large savings potential is not used.

It is also known to set an MRI system to a specific energy-saving state on an event-driven basis. For this purpose, the individual components of the MRI system communicate with one another. For example, a gradient amplifier of the MRI system may communicate with a patient table of the MRI system. Depending on a position of the patient table, the gradient amplifier may be shut down. Herein, in turn, individual components of the gradient amplifier may be shut down.

The disadvantage of the event-driven approach is that the individual components of the MRI system have to communicate with one another. Replacing a defective component (e.g., the patient table) may make it necessary also to replace another component (e.g., the gradient amplifier), since the old gradient amplifier may possibly no longer communicate with the new patient table and may no longer recognize the positions of the patient table in which it should switch to an energy-saving state. This leads to increased costs, since even non-defective components have to be replaced in some circumstances.

It is also known to set an MRI system manually to an energy-saving state.

The disadvantage of the manual approach is that the manual approach depends purely on the subjective assessment of the operating staff. In addition, the operating staff have to be very familiar with the MRI system and the different energy-saving states in order to know when the MRI system should be set to which energy-saving state. In addition, the manual approach requires manpower and, for example, time from the operating staff. Herein, the operating staff may, for example, be radiologists and/or medical technical radiology assistants (MTRAs).

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method that enables a magnetic resonance imaging (MRI) system to be set to an optimal energy-saving state is provided.

In embodiments, a method for ascertaining an optimal energy-saving state of a magnetic resonance imaging system, a method for providing a trained function, a central controller for ascertaining an optimal energy-saving state of a magnetic resonance imaging system, a magnetic resonance imaging system, a computer program product, and a computer-readable storage medium are provided.

The way in which the object is achieved according to the present embodiments is described below both in relation to apparatuses and in relation to methods. Features, advantages, or alternative embodiments are likewise also to be transferred to the other subject matter and vice versa. In other words, subject matter that, for example, is directed to a device may also be developed with the features described in connection with a method. Herein, the corresponding functional features of the method are embodied by corresponding substantive modules.

Further, the way in which the object is achieved according to the present embodiments is described both in relation to the methods and devices for ascertaining an optimal energy-saving state of a magnetic resonance imaging system and in relation to methods and devices for providing a trained function. Here, features and alternative embodiments of data structures and/or functions in methods and devices for the determination may be transferred to analogous data structures and/or functions in methods and devices for adapting/optimizing/training. Analogous data structures may, for example, be characterized by the use of the prefix “training”. Further, the trained functions used in methods and devices for ascertaining an optimal energy-saving state of a magnetic resonance imaging system may, for example, have been trained or adapted and/or provided by methods for providing the trained function.

Independent of the grammatical term usage, individuals with male, female, or other gender identities are included within the term.

The present embodiments relate to a computer-implemented method for ascertaining an optimal energy-saving state of a magnetic resonance imaging (MRI) system. The method includes a method act of receiving a set of rules with a central controller. The method further includes a method act of receiving at least one state of at least one component with the central controller. Herein, the at least one component is a component of the MRI system and/or an environment of the MRI system. Herein, the set of rules includes at least one rule by which the optimal energy-saving state may be determined based on the at least one state of the at least one component. The method further includes a method act of determining the optimal energy-saving state based on the set of rules and the at least one state of the at least one component. The method further includes a method act of providing information regarding the optimal energy-saving state.

The MRI system is configured to capture medical image data of a patient. The MRI system includes a plurality of components (e.g., a gradient amplifier, a radio-frequency amplifier, a patient table, a helium compressor, a cooling system, a computing system, a generator for detuning currents, a planning system, etc.). Individual components of the MRI system may include sub-components, such as, for example, a modulator, etc. An energy-saving state may be established by shutting down at least one component or sub-component of the MRI system or setting the at least one component or sub-component of the MRI system to a standby state. For example, a component or a sub-component may be set to standby states of different depths. The deeper the standby state, the longer it takes to activate the component.

In the method act of receiving the set of rules, the set of rules is received via an interface of the central controller. Herein, the central controller may, for example, be included by the MRI system. Herein, the set of rules may, for example, be provided by a database or a cloud system. Alternatively, the set of rules may be held as a factory setting in a memory of the MRI system and/or the central controller. For example, the set of rules may then be provided by the memory when the set of rules is received.

In the method act of receiving at least one state of at least one component, the at least one state is received by the at least one component using the interface of the central controller. Herein, the at least one component may, for example, be a component of the MRI system. Alternatively or additionally, the at least one component may be a component in an environment of the MRI system. The environment of the MRI system may, for example, be a room in which the MRI system is arranged. Hereinafter, this room is referred to as the MRI examination room. Alternatively or additionally, the environment of the MRI system may be a clinical facility that uses the MRI system. The clinical facility may, for example, be a hospital or a radiology practice or an emergency room, etc. Herein, the component in the environment may, for example, be a light switch, a heating system, an emergency button, or an input signal from an emergency room.

If the component is the patient table, the state may, for example, indicate a position of the patient table. If the component is the planning system, the state may, for example, indicate a queue of patients. In other words, the state may indicate whether one or more patients are already expected for medical imaging with the MRI system. Alternatively or additionally, the state may indicate a protocol queue. Herein, the protocol queue indicates whether a protocol is to be executed in the near future. This may, for example, be an indicator of planned medical imaging with the MRI system. If the component is the gradient amplifier, the state may indicate which sub-components of the gradient amplifier are currently active and which are in an energy-saving state. If the component is the emergency room, the state may indicate whether a patient is currently being admitted to the emergency room potentially for medical imaging with the MRI system.

The central controller is configured to communicate with at least one component of the MRI system. In other words, the central controller has at least one interface with at least one component of the MRI system. The central controller may also be configured to communicate with at least one component in the environment of the MRI system. In other words, the central controller may have an interface with at least one component in the environment of the MRI system.

Herein, the set of rules includes at least one rule. The at least one rule specifies the optimal energy-saving state in dependence on the at least one state of the at least one component. In other words, the optimal energy-saving state may be deduced based on the set of rules starting from the at least one state of the at least one component. In other words, the optimal energy-saving state may be determined based on the set of rules starting from the at least one state of the at least one component.

Herein, the optimal energy-saving state is configured such that maximum energy saving is achieved taking into account the required activation time. In one embodiment, the optimal energy-saving state may be defined by the maximum activation time. Herein, the maximum activation time specifies how quickly the MRI system has to be ready for medical imaging. The maximum activation time may, for example, be deduced from the at least one state of the at least one component. The longer the maximum activation time, the more components of the MRI system may be shut down or deactivated and/or set to a standby state or an energy-saving state. The longer the maximum activation time, the “deeper” the selected standby states may be. Alternatively, the optimal energy-saving state may also be the operating state of the MRI system. The operating state is the state in which the MRI system is ready for use at all times. For example, none of the components of the MRI system is deactivated or in a standby state in the operating state.

Thus, the set of rules may include a relationship between the at least one state of the at least one component and a maximum activation time. Alternatively, the set of rules may include a relationship between the at least one state of the at least one component and information about which component is to be set to which energy-saving state.

If, for example, a light switch in the environment of the MRI system is turned on, this may provide a reduction in the maximum activation time, and the optimal energy-saving state of the MRI system is then an energy-saving state from which the MRI system is ready for medical imaging more quickly than when the light switch is off. Similarly, when a patient enters the emergency room, the optimal energy-saving state of the MRI system may be an energy-saving state from which the MRI system is ready for medical imaging more quickly than when the emergency room is empty. Similarly, a specific position of the patient table may provide that the MRI system may be set to an energy-saving state. This and further relationships or rules may be specified in the set of rules.

Optionally, alternatively or additionally to the activation time, the optimal energy-saving state may take account of further parameters. For example, with the optimal energy-saving state, it may be taken into account that specific components of the MRI system are not to be switched on and off as often as wished in order to reduce wear. Herein, the optimal energy-saving state takes into account whether it is still advisable to switch off such a component or whether this should be avoided in order to reduce wear. Such a component is, for example, the coldhead. Alternatively, it may be advisable to restart specific components after a specific time. Restarting these components enables, for example, automatic tests to be executed or the corresponding components to be reset. With the optimal energy-saving state, it may be taken into account that such components are preferably shut down.

In the method act of determining the optimal energy-saving state, the optimal energy-saving state is determined based on the set of rules and the at least one state of the at least one component.

In the method act of providing the information regarding the optimal energy-saving state, information about the optimal energy-saving state is provided by the interface. Herein, the information may, for example, indicate how this optimal energy-saving state may be established. In other words, the information may indicate how the MRI system may be set to the optimal energy-saving state.

For example, the information may be provided such that the respective components or sub-components may deduce their specific optimal energy-saving state therefrom. For example, herein, the information is generic and may be read by each of the components or sub-components. For example, the information may include a maximum activation time. Based on this maximum activation time, each component or sub-component may decide independently which is its optimal energy-saving state. The maximum activation time may, for example, be specified in seconds, minutes, and/or hours. Alternatively, the maximum activation time may be given in categories. The categories may, for example, include “fast,” “medium,” and “long”. An alternative, and, in particular, finer, subdivision of the categories is possible.

Alternatively, the information may indicate which of the components of the MRI system is to be shut down or deactivated and/or set to a standby state or energy-saving state in order to achieve the optimal energy-saving state.

The information may, for example, be provided to a database and/or the corresponding components of the MRI system and/or the operating staff. If the information is provided to operating staff, the information may, for example, be provided by a display unit (e.g., a screen or a monitor).

The set of rules and the central controller provide that the individual components of the MRI system do not have to communicate directly with one another in order to ascertain a suitable energy-saving state of the MRI system. The central controller also allows the state of components in the environment of the MRI system to be taken into account when determining the optimal energy-saving state. For example, it is possible to take account of more components of the MRI system and/or in the environment of the MRI system than was previously possible, since the central controller replaces one-to-one communication between components and enables the different states of different components to be taken into account in a more complex way. In addition, energy-saving states of individual components that are subsequently enabled (e.g., after the MRI system has been commissioned for the first time) may be easily taken into account and integrated. In this way, it is possible to determine the optimal energy-saving state that enables maximum energy saving. The provision of the information regarding the optimal energy-saving state in generic form (e.g., in the form of the maximum activation time) enables each component to determine independently which is its optimal energy-saving state under this condition. Thus, when a component is replaced, the new component may use the same generic information to determine its optimal energy-saving state and no other components (e.g., not the set of rules) need to be adapted. Thus, based on the information regarding the optimal energy-saving state, the new component may, for example, without further changes, assume energy-saving states that, in some circumstances, may not have been possible with the previous component. In addition, in the case of a defect and/or an update or upgrade, for example, the use of the central controller in combination with a set of rules enables only individual components to be replaced and only the compatibility of the replaced components with the central controller needs to be provided. This leads to cost savings in the maintenance of the MRI system.

According to one aspect of the present embodiments, the method includes a method act of setting the MRI system to the optimal energy-saving state based on the information provided regarding the optimal energy-saving state.

Herein, the MRI system is set to the optimal energy-saving state based on the information provided. Herein, in particular, at least one component included by the MRI system is deactivated or shut down and/or set to a standby state or energy-saving state. Alternatively or additionally, herein, at least one component included by the MRI system is activated or started up.

The optimal energy-saving state may, for example, be established by setting more than one component to a specified state according to the set of rules.

To set the MRI system to the optimal energy-saving state, the above-described information regarding the optimal energy-saving state may, for example, be provided to each component. If, as described above, the information is generic (e.g., includes the maximum activation time), each component may determine which is its optimal energy-saving state under this condition. In other words, each component may then independently determine whether to set itself to an energy-saving state and, if so, to which energy-saving state.

Alternatively, the MRI system may be set to the optimal energy-saving state in that the information indicates which components are to be set to which energy-saving state in order to establish the optimal energy-saving state of the MRI system.

The MRI system may be set to the optimal energy-saving state with the described method. In this way, the operating costs of the MRI system may be reduced. In addition, the sustainability of the MRI system may be improved, since the energy saved provides that fewer resources are consumed, and, for example, fewer greenhouse gases are emitted. For example, the components themselves may determine which is their optimal energy-saving state based on the condition specified by the information. In this way, the individual components only need to understand the information regarding the energy-saving state. It is no longer necessary for the individual components to communicate with one another and/or for a central unit (e.g., the central controller) to know the possible energy-saving states for each component and select the optimal state. This makes maintenance and replacement of components easier and more cost-effective.

According to a further aspect of the present embodiments, the method is initiated by a time trigger. Alternatively or additionally, the method is initiated by a change of state of the at least one state of the at least one component. Alternatively or additionally, the method is initiated by receiving user input.

If the method is initiated by a time trigger, the at least one state of the at least one component is retrieved or received, for example, at at least one specific point in time and/or at specific time intervals, and the optimal energy-saving state is determined again based on the current state as described above.

If the method is initiated by a change in the state of the at least one component, the method is initiated on a change to the at least one state of the at least one component. For example, the optimal energy-saving state for the changed state is then determined when the at least one state of the at least one component changes.

If the method is initiated by user input, a user (e.g., the operating staff) may initiate the determination of the optimal energy-saving state. Herein, the user input may, for example, be received by an input. Herein, the input may be a keyboard and/or a touchscreen and/or a computer mouse.

For example, the method may be initiated by any of the three aforementioned options.

Time-controlled initiation provides that it is checked at regular intervals whether the current energy-saving state or the current state of the MRI system still corresponds to the optimal energy-saving state. Herein, the current state of the MRI system may also be the operating state. The method initiated by a change in the state provides that the set state of the MRI system still corresponds to the optimal energy-saving state after a change in the state. Manual initiation enables the optimal energy-saving state to be ascertained or determined, for example, when a user (e.g., the operating staff) considers this to be necessary.

According to a further aspect of the present embodiments, the rule may be adapted in dependence on access authorization.

The access authorization indicates who is authorized to adapt or change the set of rules and, for example, the rule included by this set of rules.

For example, the at least one rule may only be adapted by a manufacturer of the MRI system. The access authorization may then also be configured such that only the manufacturer may adapt the at least one rule.

Alternatively or additionally, the access authorization may give operating staff authorization to adapt the at least one rule.

Herein, the adaptation may include activating or deactivating a rule. Alternatively, the adaptation may include adaptation of the content of a rule. In the case of the adaptation of the content, for example, the components that are to be shut down may be adapted. Alternatively or additionally, in the case of an adaptation of the content, at least one parameter describing the at least one state of the at least one component in which the corresponding rule is to be executed may be adapted. The parameter may, for example, be a coordinate of a position of the patient table. Alternatively, the adaptation may be the deletion of the rule.

Alternatively, the access authorization may prohibit the adaptation of the rule.

For example, the set of rules may include more than one rule. For example, the adaptation of different rules may be regulated by different access authorizations. Herein, for example, a rule may only be adapted by the manufacturer, a further rule may only be adapted by the operating staff, and a further rule may be adapted by the manufacturer and the operating staff.

In this way, it may be provided that necessary rules cannot be adapted or may only be adapted by the manufacturer. The access authorization may provide users (e.g., the operating staff) with the possibility of adapting individual rules of the set of rules according to requirements. In this way, the operating staff may be provided with the possibility of adapting the set of rules, on condition that necessary rules cannot be adapted or may only be adapted by the manufacturer, and thus, a mode of operation and specific energy-saving behavior of the MRI system may be specified and provided.

According to an optional aspect of the present embodiments, the set of rules may be adapted in dependence on access authorization.

Herein, the access authorization may be embodied as described above.

Herein, the set of rules may be adapted by adapting and/or deleting an existing rule and/or by adding a new rule. Herein, the adaptation of the set of rules may also be regulated by the access authorization. Herein, the access authorization may vary depending on the rule.

The access authorization may regulate who is allowed to change the set of rules (e.g., who is allowed to add and/or delete a rule).

According to a further aspect of the present embodiments, the method also includes a method act of receiving optional user input regarding the optimal energy-saving state with the central controller. Herein, when providing the information on the optimal energy-saving state, the information regarding the optimal energy-saving state provided by the user input is provided if user input has been received.

In the method act of receiving the user input, the user input is received by the interface of the central controller if user input is provided. Herein, the user input is optional. In other words, the user input may be provided by users (e.g., by the operating staff). Then, the optimal energy-saving state is determined as the energy-saving state provided by the user input. If no user input is received, the optimal energy-saving state is determined as described above based on the set of rules and the at least one state of the at least one component. In other words, therefore, the user input, if provided, may override the optimal energy-saving state as described above.

The user input may, for example, specify the optimal energy-saving state generically (e.g., in the form of a maximum activation time). Alternatively, the user input may specify which components are to be set to which energy-saving state.

The interface with which the user input is received may, for example, be a keyboard and/or a touchscreen and/or a computer mouse and/or voice input (e.g., a microphone).

Optionally, receiving user input enables it to be provided that the user may freely decide at any time to which energy-saving state the MRI system is to be set.

For example, in this way, a user may prevent the MRI system from being set to an energy-saving state or from being set to an undesired energy-saving state from which it takes a relatively long time until the MRI system is ready for use again. In this way, it may be taken into account that the user may know in advance when a patient is coming or that another patient is coming. For example, the user may prevent the MRI system from being set to an energy-saving state in the event of an emergency and in this way provide that the MRI system is ready for use for this emergency at any time. Alternatively, the user may specify another energy-saving state from which the MRI system is ready for use again more quickly, for example.

According to a further aspect of the present embodiments, the method includes a method act of receiving time information with the central controller. Herein, the set of rules also includes a rule relating to the time information. Herein, the rule relating to the time information is taken into account when determining the optimal energy-saving state.

Herein, the time information may, for example, include a time of day. The time information may also include a date. Herein, the rule relating to the time information may indicate that the MRI system is to be set to a specific optimal energy-saving state with specific time information. For example, the rule may specify that every evening (e.g., at 10 p.m.), the MRI system is set to an optimal energy-saving state for, for example, seven hours from which it takes a relatively long time to reactivate the MRI system. Alternatively or additionally, the rule may specify that the MRI system is also set to this optimal energy-saving state every Friday (e.g., at 10 p.m.) for 55 hours, for example.

Alternatively or additionally, the time information may include a time interval since a last change in the state of one of the components. The at least one rule relating to the time information of the set of rules may then specify that, if the time interval exceeds a specific duration, the MRI system is set to an optimal energy-saving state.

The above-described method may be combined with the time-controlled method. This may be taken into account in the set of rules. In this way, the advantage of a night shutdown and/or a weekend shutdown of the MRI system may be retained.

According to a further aspect of the present embodiments, the set of rules includes a trained function. Herein, when determining the optimal energy-saving state, the trained function is applied to the at least one state of the at least one component. Herein, the optimal energy-saving state is determined.

In the method act of applying the trained function, the output data is generated by the first trained function based on the input data.

In general, a trained function mimics cognitive functions that humans associate with human thinking. For example, training based on training data enables the trained function to adapt to new circumstances and to recognize and extrapolate patterns.

In general, parameters of a trained function may be adapted by training. For example, supervised training, semi-supervised training, unsupervised training, reinforcement learning, and/or active learning may be used for this purpose. In addition, representation learning (an alternative term is “feature learning”) may be used. For example, the parameters of the trained functions may be adapted iteratively in a plurality of training steps.

For example, a trained function may include a neural network, a support vector machine, a random tree or decision tree, and/or a Bayesian network, and/or the trained function may be based on k-means clustering, Q-learning, genetic algorithms, and/or association rules. For example, a trained function may include a combination of a plurality of uncorrelated decision trees or an ensemble of decision trees (e.g., random forest). For example, the trained function may be determined by XGBoosting (e.g., eXtreme Gradient Boosting). For example, a neural network may be a deep neural network, a convolutional neural network, or a convolutional deep neural network. Further, a neural network may be an adversarial network, a deep adversarial network, and/or a generative adversarial network. For example, a neural network may be a recurrent neural network. For example, a recurrent neural network may be a long-short-term-memory (LSTM) network (e.g., a gated recurrent unit (GRU)). For example, a trained function may include a combination of the described approaches. For example, the approaches described here for a trained function are referred to as network architecture of the trained function.

Thus, the trained function specifies the set of rules or comprises the set of rules.

The set of rules may be implemented or represented or specified by a trained function. In this way, the set of rules may be adapted particularly well to the needs of users or operating staff.

According to a further aspect of the present embodiments, a component of the at least one component is a patient table, a computing system of the MRI system, a planning system, an emergency entrance, or an MRI examination room.

Herein, the state, for example, indicates a status of the components.

Herein, the patient table is configured to support a patient during medical imaging with the MRI system. Herein, the patient table may assume various positions. For example, the patient table may assume a starting position or resting position when no patient is supported on the patient table. Herein, the state of the patient table describes the position of the patient table.

Herein, the computing system may, for example, describe a status and hence a state of the MRI system. For example, the computing system may indicate whether the MRI system is currently in use or active. For example, the computing system may indicate whether the computing system is currently in an energy-saving state and, if so, in which state.

The planning system is configured for examination planning. For example, the planning system may include a queue of patients. In other words, the operating staff may indicate in the planning system which patient is to undergo medical imaging with the MRI system and when. Herein, the state of the planning system may indicate whether at least one patient is listed in the queue. Alternatively or additionally, the planning system may include a protocol queue. Herein, the protocol queue may indicate which protocol or protocols is/are to be executed next and at which point in time. Herein, the protocol queue may be correlated with the patient queue. In this case, correlated provides that at least one protocol is listed in the protocol queue for each patient in the queue. Herein, the state of the planning system may indicate whether at least one protocol is listed in the protocol queue or included thereby.

The emergency entrance may be included by an emergency room. Herein, the state of the emergency entrance may indicate whether there is a patient in the emergency room. For example, the state of the emergency entrance may indicate whether a patient who potentially requires medical imaging with the MRI system is in the emergency room.

The MRI examination room may, for example, include at least one sub-component. For example, a light switch and/or a heating system may be one of the sub-components of the MRI examination room. Herein, the state of the MRI examination room may, for example, indicate whether the light switch is on or off. Alternatively or additionally, the state of the examination room may indicate whether the heating system is on or off or the temperature to which the heating system is set.

For example, the states of these components may be taken into account when determining the optimal energy-saving state. The states of these components may be used to recognize in a timely manner and reliably when the MRI system is needed promptly or when the MRI system is not needed.

The present embodiments also relate to a computer-implemented method for providing a trained function. The method includes a method act of receiving at least one state of at least one component. The method also includes a method act of receiving information regarding an optimal energy-saving state. Herein, the information regarding the optimal energy-saving state depends on the at least one state of the at least one component. The method also includes a method act of training a function based on the at least one state of the at least one component and the information regarding the optimal energy-saving state. The method also includes a method act of providing the trained function.

Herein, the at least one state of the at least one component is, for example, configured as described above. Herein, the information regarding the optimal energy-saving state is, for example, configured as described above.

In a first act, the optimal energy-saving state may be specified based on a fixed set of rules in dependence on the at least one state of the at least one component. In other words, in a first act, an optimal energy-saving state for the at least one state of the at least one component may be specified by a rule included by a fixed set of rules. Herein, the set of rules and, for example, the at least one rule are configured as described above.

Herein, the optimal energy-saving state for the at least one state of the at least one component may be retrieved from a database in the method act of receiving the optimal energy-saving state.

Optionally, alternatively or additionally, the optimal energy-saving state may be provided by user input. Herein, for example, the user input may specify the optimal energy-saving state regarding the at least one state of the at least one component. If the user input is provided in addition to the optimal energy-saving state based on a fixed set of rules, the user input overwrites the optimal energy-saving state based on the fixed set of rules. In other words, the further method is then continued based on the optimal energy-saving state provided by the user input.

The user input may, for example, be provided by input by the operating staff. The user input may be received by an input unit. The input unit may be, for example, a keyboard, a touchscreen, and/or a computer mouse.

Optionally, the user input may only be received if access authorization allows manual provision of the optimal energy-saving state by user input.

Optionally, the user input may also include any activity of operating staff on the MRI system and/or in the environment of the MRI system. For example, the user input may, for example, include a key press and/or a door contact and/or an input by the operating staff using an input device (e.g., using a touchpad or touchpanel), and/or independent changes of state of individual components (e.g., a cooling system) and/or changes in a computer system (e.g., in a radiology information system) and/or a change in the environment of the MRI system. For example, this enables events that trigger a switch to an energy-saving state to be learned or recognized.

In the method act of training the function, the function is applied to the at least one state of the at least one function. Herein, a training energy-saving state is determined. This training energy-saving state is compared with the received optimal energy-saving state. If the training energy-saving state differs from the received optimal energy-saving state, at least one parameter of the function is varied. Herein, the at least one parameter is varied such that when the function varied in this way is reapplied to the at least one state of the at least one component, the training energy-saving state corresponds better to the received optimal energy-saving state. This is repeated iteratively until, when the varied function is applied to the at least one state of the at least one component, the training energy-saving state corresponds to the received optimal energy-saving state. The varied function is then the trained function.

During training, the function may, for example, be trained as described based on a plurality of states of a plurality of components and an associated plurality of optimal energy-saving states.

During the provision of the trained function, the trained function is provided such that the trained function may be used in the above-described method. For example, the trained function then represents the set of rules for the above-described method or includes the same.

The set of rules may be mapped or represented by a trained function. The application of the trained function to the at least one state of the at least one component enables the optimal energy-saving state to be determined in a simple and efficient manner. The trained function may, for example, be trained by supervised learning. This is at least a first step for training the trained function.

According to one aspect of the present embodiments, the training is based on decentralized distributed training.

Decentralized or distributed training is also referred to as “federated learning.”

For example, in this way, the function may be trained in a decentralized manner as described above. With decentralized training, the function is trained locally in various institutions (e.g., hospitals and/or radiology practices). The functions trained locally in this way may then be combined centrally to form a common trained function.

With local or decentralized training, the received optimal energy-saving state may be modified or specified locally by operating staff with respect to at least one state of at least one component. In other words, each institution may have a slightly different set of rules.

In this way, preferences of different operating staff from different institutions may be taken into account in the trained function. The decentralized distributed training provides no data has to be transferred outside the institution. This may, for example, minimize the risk of data leakage for the individual institutions.

According to a further aspect of the present embodiments, the training takes place continuously during the execution of the above-described method. Herein, the received optimal energy-saving state is the optimal energy-saving state determined with the above-described method. Herein, the method for providing the trained function also includes a method act of receiving information about a degree with which the trained function is to be continuously further trained. Herein, the degree is taken into account when training the function.

With continuous training, the trained function is also continuously further trained during application in the above-described method. Herein, the optimal energy-saving state may be determined as described above by applying the trained function or by optional user input or by time information.

The degree may indicate the extent to which changes or adaptations of the optimal energy-saving state during application (e.g., optional user input during continuous training) may be taken into account. For example, the degree may indicate that a one-off adaptation may not be taken into account. For example, the degree may indicate that a permanent change or adaptation may be taken into account.

Taking into account the optional user input enables the trained function to be personalized (e.g., retrained specifically for an institution or specific operating staff). The degree may, for example, specify whether a one-off adaptation may be taken into account during the training or whether only repeated or permanent adaptation may be taken into account. In this way, the degree of personalization of the trained function may be taken into account.

The present embodiments also relate to a central controller for ascertaining an optimal energy-saving state of an MRI system. The central controller includes an interface and a computing unit. Herein, the interface and the computing unit are configured to execute the following method acts: receiving a set of rules; receiving at least one state of at least one component, where the at least one component is a component of the magnetic resonance imaging system and/or an environment of the magnetic resonance imaging system, and where the set of rules includes at least one rule by which an optimal energy-saving state may be determined based on the at least one state of the at least one component; determining the optimal energy-saving state based on the set of rules and the at least one state of the at least one component; and providing information regarding the optimal energy-saving state.

Such a central controller may, for example, be configured to execute the above-described method for ascertaining an optimal energy-saving state of an MRI system and the aspects thereof. The central controller is configured to execute this method and the aspects thereof in that the interface and the computing unit are configured to execute the corresponding method acts.

The present embodiments also relate to a magnetic resonance imaging system including a central controller as described above.

The magnetic resonance imaging (MRI) system may include a medical and/or diagnostic magnetic resonance device configured to capture medical and/or diagnostic image data (e.g., medical and/or diagnostic MRI image data) of a patient. The magnetic resonance device, and hence the MRI system, are thus configured for medical imaging. For this purpose, the magnetic resonance device includes a scanner unit. The scanner unit of the magnetic resonance device may include a detector unit for capturing the medical and/or diagnostic image data. In one embodiment, the scanner unit includes, for example, a magnet unit of the scanner unit, a body coil, a main magnet, a gradient coil unit, and a radio-frequency antenna unit. The radio-frequency antenna unit is arranged permanently within the scanner unit and configured and/or embodied to emit an excitation pulse. To capture the magnetic resonance signals, the magnetic resonance device may have local radio-frequency coils or local coils arranged around the region of interest of the patient.

The main magnet of the scanner unit is configured to generate a homogeneous main magnetic field with a defined and/or specific magnetic field strength, such as, for example, with a defined and/or specific magnetic field strength of 3 T or 1.5 T, etc. For example, the main magnet is configured to generate a strong, constant, and homogeneous main magnetic field. The homogeneous main magnetic field may be arranged or located within the patient receiving area of the magnetic resonance device. The gradient coil unit is configured to generate magnetic field gradients used for spatial encoding during imaging.

The patient receiving area is configured and/or embodied to receive the patient (e.g., the region of interest of the patient) for a medical magnetic resonance examination or examination. For example, for this purpose, the patient receiving area may be configured as cylindrical in shape and/or surrounded by the scanner unit in a cylindrical shape. For this purpose, the scanner unit has an enclosure of the housing unit that at least partially surrounds the patient receiving area. The enclosure surrounding the patient receiving area may, for example, also be configured in one part and/or in one piece with the side of the radio-frequency antenna unit of the scanner unit facing the patient receiving area or may also be configured separately from the radio-frequency antenna unit of the scanner unit.

If the patient is moved into the MRI system or the body coil, the patient is, for example, positioned in the patient receiving area.

A field of view (FOV) and/or an isocenter of the magnetic resonance device may be arranged within the patient receiving area. The FOV may include a capturing area of the magnetic resonance device within which the conditions for capturing medical image data (e.g., MRI image data) are present, such as, for example, a homogeneous main magnetic field. The isocenter of the magnetic resonance device may include the area and/or point within the magnetic resonance device that has the optimal and/or ideal conditions for capturing medical image data (e.g., magnetic resonance image data). For example, the isocenter includes the most homogeneous magnetic field area within the magnetic resonance device.

The patient support device is configured to position and/or support the patient for an examination. Herein, the patient support device includes the patient table that is configured to be moved into the patient receiving area. For a magnetic resonance examination, the patient is positioned on the patient table such that the region of interest is arranged and/or positioned within the isocenter of the patient receiving area after positioning or moving the patient table along the travel path within the patient receiving area.

For communication and/or information exchange between the patient and the medical operating staff during an examination, the magnetic resonance device has a communication unit. The communication unit may have a communication element on the user side, such as, for example, a communication console for inputting and/or outputting communication data, such as, for example, information. Further, the communication unit also has at least one communication element on the patient side. For example, the communication unit has an acoustic and/or visual communication element. The acoustic, communication element may, for example, be a loudspeaker or a microphone. The visual communication element may, for example, be a screen (e.g., a touchscreen).

The present embodiments also relate to a computer program product with a computer program and a computer-readable medium (e.g., a non-transitory computer-readable storage medium). An extensively software-based implementation has the advantage that it is also easily possible to retrofit central control systems used to date by a software update in order to work in the manner described. In addition to the computer program, such a computer program product may optionally include additional components such as, for example, documentation and/or additional parts, and hardware components, such as, for example, hardware keys (e.g., dongles, etc.) for using the software.

For example, the present embodiments also relate to a computer program product with a computer program that may be loaded directly into a memory of a central controller, with program sections for executing all the acts of the above-described method for ascertaining an optimal energy-saving state of an MRI system and the aspects thereof when the program sections are executed by the central controller.

For example, the present embodiments relate to a computer-readable storage medium (e.g., a non-transitory computer-readable storage medium) on which program sections that are readable and executable by a central controller are stored for executing all the acts of the above-described method for ascertaining an optimal energy-saving state of an MRI system and the aspects thereof when the program sections are executed by the central controller.

The present embodiments also relate to a training system for providing a trained function. The training system includes a training interface and a training computing unit. Herein, the training interface and the training computing unit are configured to execute the following method acts: receiving at least one state of at least one component; receiving information regarding an optimal energy-saving state, where the information regarding the optimal energy-saving state depends on the at least one state of the at least one component; training a function based on the at least one state of the at least one component and the information regarding the optimal energy-saving state; and providing the trained function.

Such a training system may, for example, be configured to execute the above-described method for providing a trained function and the aspects thereof. The training system is configured to execute this method and the aspects thereof in that the training interface and the training computing unit are configured to execute the corresponding method acts.

The present embodiments also relate to a training computer program product with a training computer program and a computer-readable training medium. An extensively software-based implementation has the advantage that it is also easily possible to retrofit training systems used to date by a software update in order to work in the manner described. In addition to the training computer program, such a training computer program product may optionally include additional parts, such as, for example, documentation and/or additional components, and hardware components, such as, for example, hardware keys (e.g., dongles, etc.) for using the software.

For example, the present embodiments also relate to a training computer program product with a training computer program that may be loaded directly into a training memory of a training system, with training program sections for executing all the acts of the above-described method for providing a trained function and the aspects thereof when the training program sections are executed by the training system.

For example, the present embodiments relate to a computer-readable training storage medium (e.g., a non-transitory computer-readable storage medium) on which training program sections that are readable and executable by a training system are stored for executing all the acts of the above-described method for providing a trained function and the aspects thereof when the training program sections are executed by the training system.

The above-described properties, features, and advantages of the present embodiments will be clearer and more plainly comprehensible in conjunction with the following figures and the descriptions thereof. Herein, the figures and descriptions are not intended to restrict the invention and the embodiments thereof in any way.

In different figures, the same components are provided with corresponding reference symbols. The figures are generally not to scale.

### BRIEF DESCRIPTION OF THE DRAWINGS

FIG. 1 shows an example embodiment of a method for ascertaining an optimal energy-saving state of a magnetic resonance imaging (MRI) system;

FIG. 2 shows an example embodiment of a method for providing a trained function;

FIG. 3 shows a central controller for ascertaining an optimal energy-saving state of an MRI system;

FIG. 4 shows a training system for providing a trained function; and

FIG. 5 shows an example embodiment of an MRI system.

### DETAILED DESCRIPTION

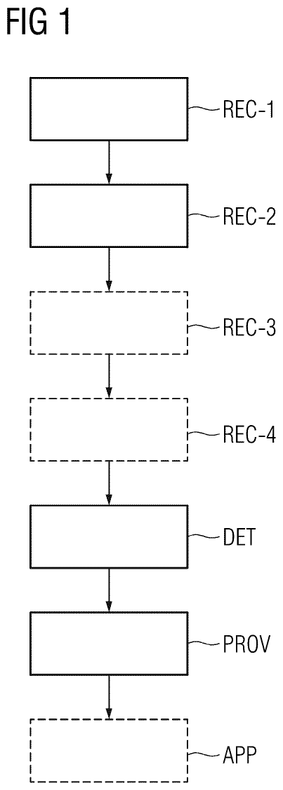

FIG. 1 shows an example embodiment of a method for ascertaining an optimal energy-saving state of a magnetic resonance imaging (MRI) system 1.

In a method act of receiving REC-1 a set of rules, the set of rules is received by an interface SYS.IF of a central controller SYS. For example, the set of rules may be provided by a database for this purpose.

The method includes a further method act of receiving REC-2 at least one state of at least one component by the interface SYS.IF of the central controller SYS.

Herein, the at least one component is a component of the MRI system 1 and/or is in the environment of the MRI system 1.

For example, the at least one component may be a patient table 15 of the MRI system 1, a computing system of the MRI system 1, or a planning system of the MRI system 1. Alternatively, the at least one component may be an emergency entrance of an emergency room in the environment of the MRI system 1 or an MRI examination room.

Herein, the patient table 15 of the MRI system 1 is configured to support a patient during medical imaging with the MRI system 1. Herein, the patient table 15 may assume various positions. Herein, the state of the patient table 15, for example, describes which position the patient table 15 assumes at this point in time. For example, it may be recognized when the patient table 15 is in a resting position or waiting position. In the resting position, no patient is positioned on the patient table and also no patient is currently being positioned. A resting position of the patient table 15 may indicate that the MRI system 1 will not be used for a specific period of time.

The computing system is configured to control the MRI system 1. For example, medical imaging with the MRI system 1 may be controlled by the computing system. The state of the computing system, for example, describes whether medical imaging is currently being performed with the MRI system 1. For example, it may be deduced from the state of the computing system that the MRI system 1 is active and should not be set to a deactivated state (e.g., an energy-saving state).

The planning system of the MRI system 1 is, for example, configured to capture a queue of patients for whom medical imaging is to be performed with the MRI system 1. For example, medical operating staff may input the patient on whom medical imaging is to be performed with the MRI system 1. Alternatively or additionally, the planning system may be configured to capture a protocol queue. The protocol queue indicates when which protocol for medical imaging is to be executed with the MRI system 1. For example, the protocol queue may be correlated with the patient queue. Herein, each patient in the queue may be assigned one or more protocols in the protocol queue. The state of the planning system then indicates whether at least one patient is included by the queue and/or whether at least one protocol is included by the protocol queue. If at least one patient or at least one protocol is included by the queue or the protocol queue, it is possible to read from the planning system when the medical imaging of the at least one patient and/or with the at least one protocol is planned and to deduce from this when the MRI system 1 should be ready for use or active.

The emergency entrance may, for example, be the entrance to an emergency room in the environment of the MRI system 1. For example, the emergency entrance may be an entrance to an emergency room of a hospital. The state of the emergency entrance indicates whether a patient is currently located in the emergency room. For example, the state of the emergency entrance may indicate whether a patient located in the emergency room potentially requires medical imaging with the MRI system 1. For example, it may be deduced from the state of the emergency entrance whether the MRI system 1 should be preventively set to an active state or operating state or at least to an energy-saving state from which the MRI system 1 may be activated quickly or is ready for use.

The MRI examination room, for example, includes the MRI room 26 in which a magnetic resonance device 10 included by the MRI system 1 is positioned. For example, the MRI examination room may also include a control room 27 from which the MRI system 1 is controlled. Herein, the MRI examination room may, for example, include one or more sub-components. A sub-component of the MRI examination room may, for example, be a light switch and/or a heating system. Herein, the state of the MRI examination room may indicate whether the light switch is on or off and/or the temperature to which the heating system is set. It may be deduced from the state of the MRI examination room whether medical imaging with the MRI system is planned in the near future. For example, a light switch set to “on” may indicate that there are people in the MRI examination room and thus medical imaging is about to take place. For example, it may be deduced from the temperature of the heating system whether medical imaging is about to take place or whether the heating is, for example, lowered at night and no examination is expected to take place.

Herein, the set of rules includes at least one rule. Herein, the rule specifies a dependency between the at least one state of the at least one component and an optimal energy-saving state. In other words, the rule may be used to determine the optimal energy-saving state based on the at least one state of the at least one component.

The optimal energy-saving state is a state of the MRI system 1 in which one or more components are deactivated or shut down or in a standby state or energy-saving state. Depending on which components of the MRI system are deactivated and/or in a standby state, it may take different lengths of time until the MRI system 1 is again ready for use or fully active. Alternatively, the optimal energy-saving state of the MRI system 1 may be a state in which all components of the MRI system 1 are active and the MRI system 1 is thus immediately ready for use at any time. This state is also referred to as the operating state.

The optimal energy-saving state may be indirectly specified, for example, by a maximum activation time. The maximum activation time indicates the time within which the MRI system 1 is to be ready for use again. Thus, the maximum activation time sets a condition for the optimal energy-saving state. The maximum activation time may be given in the form of an actual time (e.g., 0 s, 30 min, 1 h, 5 h etc.). Alternatively, the maximum activation time may be given in the form of categories that describes how quickly the MRI system 1 should be ready for use. The categories may, for example, include a traffic light system.

Herein, the MRI system includes a plurality of components that may be deactivated and/or set to a standby state (e.g., a gradient amplifier, a radio-frequency amplifier, a patient table, a helium compressor, a cooling system, a computing system, a generator for detuning currents, a planning system etc.). Individual components of the MRI system may include sub-components, such as, for example, a modulator, etc. An energy-saving state of the MRI system 1 may be established by deactivating or shutting down at least one component or sub-component of the MRI system and/or setting the at least one component or sub-component of the MRI system to a standby state or energy-saving state.

In a method act of determining DET the optimal energy-saving state, the optimal energy-saving state is determined based on the set of rules and the at least one state of the at least one component. For example, herein, the optimal energy-saving state is determined by the at least one rule included by the set of rules.

In a method act of providing PROV information regarding the optimal energy-saving state included by the method, the information regarding the optimal energy-saving state is, for example, provided by the interface SYS.IF.

The information may, for example, be generic and configured such that a corresponding component or sub-component of the MRI system 1 may deduce from this information whether the corresponding component or sub-component of the MRI system 1 should be set to an energy-saving state and, if so, to which state. For example, the information may indicate the maximum possible activation time. Based on this, each individual component may decide independently whether the respective individual component should be set to an energy-saving state and, if so, to which state.

Alternatively, the information may, for example, include information about which components of the MRI system 1 are to be deactivated and/or set to a standby state and/or which components of the MRI system 1 are to be activated and/or set to a standby state. The information can, for example, be provided to a database. Alternatively or additionally, the information may be provided to operating staff. Alternatively or additionally, the information may be provided to the components so that the corresponding actions may be performed on the components and the components may be set to the corresponding state.

In an optional method act of setting APP the MRI system 1 to the optimal energy-saving state, the MRI system 1 is set to the optimal energy-saving state based on the information provided. For example, based on the information provided, at least one component of the MRI system 1 or component included by the MRI system 1 may be deactivated or shut down and/or set to a standby state or energy-saving state and/or activated.

In one embodiment, the components of the MRI system 1 may independently decide which is their optimal energy-saving state based on the information provided. For this purpose, as described above, the information may be generic. For example, the information may specify the maximum activation time. Based on this, when the MRI system 1 is set to the optimal energy-saving state, each component may independently determine the energy-saving state to which the respective component may switch in order to be ready for use again within the maximum activation time.

Optionally, the method also includes a method act of receiving REC-3 an optional user input regarding the optimal energy-saving state by the interface SYS.IF of the central controller SYS. Herein, the user input may, for example, be provided by operating staff. Herein, the operating staff may be radiologists and/or MRTAs. The user input may define a one-off rule. In other words, the user input may be configured for a one-off definition of the optimal energy-saving state. Alternatively, the user input may be configured to permanently change a rule included by the set of rules relating to the at least one state of the at least one component. The user input is configured to overwrite the optimal energy-saving state determined by the set of rules. The user input may specify the alternative optimal energy-saving state in the form of a maximum activation time, for example. Alternatively, the user input may specify which component is to be set to which energy-saving state. In the method act of determining the optimal energy-saving state, the information regarding the optimal energy-saving state received with the user input is then provided. Herein, the user input is optional.

Optionally, the method also includes a method act of receiving REC-4 time information by the interface SYS.IF of the central controller SYS. Herein, the time information may, for example, include a time of day and/or a date. Alternatively or additionally, the time information may include a predefined time period.

The set of rules then also includes a rule relating to the time information. If the time information includes a time of day, the rule may specify an optimal energy-saving state in dependence on the time of day. For example, the rule may specify that a specific energy-saving state is always optimal for the MRI system 1 at a specific time in the evening. The rule may then also specify that another energy-saving state is optimal from a specific time in the morning. In this way, it is, for example, possible to implement a night shutdown without having to analyze the states of individual components. A shutdown provides that one or more components of the MRI system 1 is deactivated or set to a standby state. For example, a new optimal energy-saving state may be determined for the period of the shutdown. If the time information includes a date, in this way, it is similarly possible to implement a shutdown (e.g., over a weekend or public holiday). Optionally, it is also possible to take account of a shift schedule. A shutdown as described above may be carried out for times and/or dates when no operating staff are entered in the shift schedule. If the time information includes a predefined time period (e.g., if no change in the at least one state of the at least one component has occurred within this time period), a shutdown as described above may be carried out by determining a new optimal energy-saving state.

The rule relating to this time information is taken into account when determining DET the optimal energy-saving state.

Optionally, the above-described method may be initiated by a time trigger. In other words, the method may be executed after a predetermined time period has elapsed. In other words, the method may be executed regularly after a predetermined time period has elapsed. In other words, the at least one state of the at least one component is received when the predetermined time period has elapsed, and the optimal energy-saving state is determined based thereon. Thus, for example, the timeliness of the current optimal energy-saving state is checked when the predetermined time period has elapsed.

Alternatively or additionally, the method may optionally be initiated by a change in the state of the at least one state of the at least one component. In other words, a change in the at least one state of the at least one component may initiate the method. For example, the optimal energy-saving state is redetermined or adapted in the event of a change in the at least one state of the at least one component.

Alternatively or additionally, the method may optionally be initiated by receiving user input. In other words, operating staff may initiate a redetermination of the optimal energy-saving state using user input. In other words, the method may be initiated by manual input or manually.

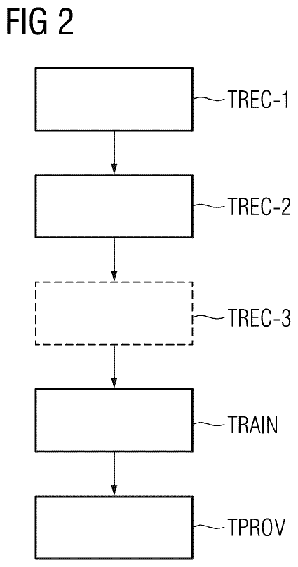

Optionally, the set of rules may include a trained function. Herein, the trained function may be configured as described above. For example, the trained function may be trained with the method described according to FIG. 2. Optionally, the trained function may be continuously further trained. When determining DET the optimal energy-saving state, the trained function is applied to the at least one state of the at least one component. Herein, the optimal energy-saving state is determined.

Optionally, the at least one rule may be adapted in dependence on access authorization. For example, the at least one rule may be adapted manually in dependence on the access authorization (e.g., by operating staff and/or by a manufacturer and/or by maintenance staff or service staff). For example, the at least one rule may be adapted once. Alternatively, the at least one rule may be adapted permanently. Herein, the access authorization regulates whether the at least one rule may be adapted. In addition, the access authorization regulates who may adapt the at least one rule. In some embodiments, a rule that cannot be adapted by the operating staff may be deactivated. In other words, in some embodiments, such a rule may be deactivated by the operating staff and thus not be applied when determining DET the optimal energy-saving state.

FIG. 2 shows an example embodiment of a method for providing a trained function.

The method includes a method act of receiving TREC-1 at least one state of at least one component with a training interface TSYS.IF of a training system TSYS. Herein, the at least one state is, for example, configured as described with respect to FIG. 1. Herein, the at least one component is, for example, configured as described with respect to FIG. 1.

The method also includes a method act of receiving TREC-2 information regarding an optimal energy-saving state. Herein, the information regarding the optimal energy-saving state is, for example, configured as described with respect to FIG. 1. Herein, the information regarding the optimal energy-saving state depends on the at least one state of the at least one component. For example, this dependency may be specified in a rule included by a set of rules that is configured in accordance with the description of FIG. 1. Alternatively, the information regarding the optimal energy-saving state and the at least one state of the at least one component may be specified manually (e.g., by user input). For example, the user input may overwrite the rule included by the set of rules.

The method further includes a method act of training TRAIN the function based on the at least one state of the at least one component and the information regarding the optimal energy-saving state. For example, herein, the function is applied iteratively numerous times to the at least one state of the at least one component. Herein, at least one parameter of the function is adapted. Herein, the at least one parameter of the function is adapted until the optimal energy-saving state is determined when the function is applied. This function adapted in this way is referred to as a trained function.

The method also includes a method act of providing TPROV the trained function. Herein, the trained function is provided such that the trained function may be applied in the method described according to FIG. 1.

Optionally, the training TRAIN may be based on decentralized distributed training. In other words, the function may be trained in a decentralized manner in different institutions independently of one another as described above. Herein, an institution may, for example, be a hospital or a radiology practice or a hospital group. The functions trained in this distributed manner may then be combined centrally to form a common trained function, which is applied in the method described according to FIG. 1 for determining DET the optimal energy-saving state.

Optionally, the trained function may be continuously further trained by a feedback loop during application in the method in FIG. 1. For example, the at least one parameter may be further adapted in dependence on user input regarding the optimal energy-saving state described according to FIG. 1. For example, the further training may be carried out according to the described training method.

Optionally, the method may include a method act of receiving TREC-3 information about a degree with which the trained function is to be continuously further trained. Herein, the degree is taken into account when training TRAIN the function. For example, the degree may indicate how greatly the at least one parameter is to be adapted based on the user input during continuous training of the function. Alternatively or additionally, the degree may indicate how often the same user input is to be received before it is taken into account for continuous further training.

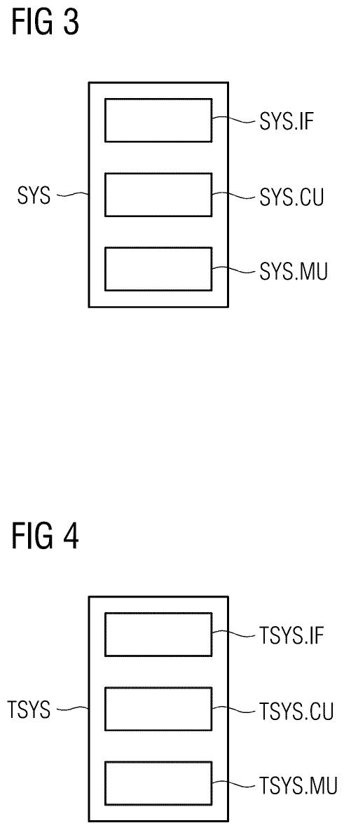

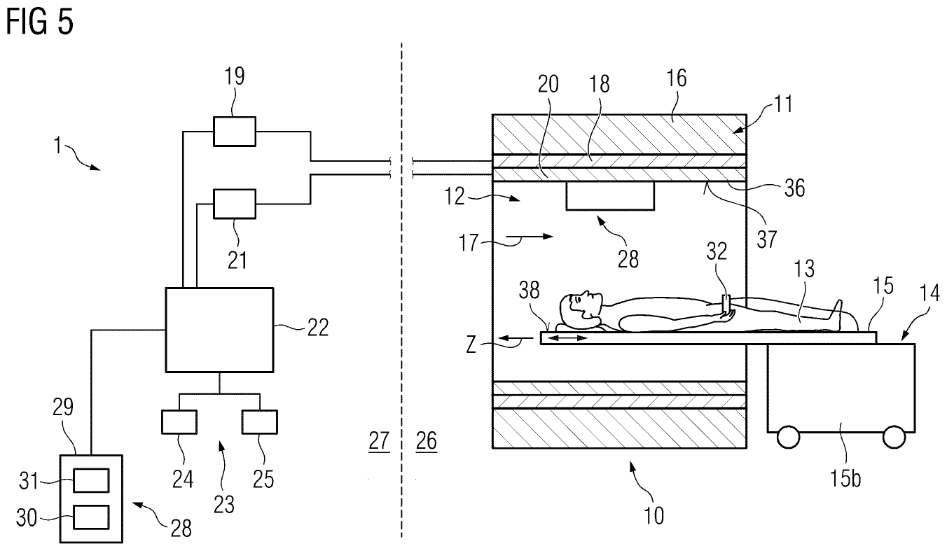

FIG. 3 shows a central controller SYS for ascertaining an optimal energy-saving state of an MRI system 1, and FIG. 4 shows a training system TSYS for providing a trained function.

The central controller SYS depicted for ascertaining an optimal energy-saving state of an MRI system 1 is configured to execute a method according to the present embodiments for ascertaining an optimal energy-saving state of an MRI system 1. The training system TSYS depicted is configured to execute a method according to the present embodiments for providing the trained function. The central controller SYS includes an interface SYS.IF, a computing unit SYS.CU, and a memory unit SYS.MU. The training system TSYS includes a training interface TSYS.IF, a training computing unit TSYS.CU, and a training memory unit TSYS.MU.

The central controller SYS and/or the training system TSYS may, for example, be a computer, a microcontroller, or an integrated circuit (IC). Alternatively, the central controller SYS and/or the training system TSYS may be a real or virtual computer network (e.g., a technical term for a real computer network is “cluster”, a technical term for a virtual computer-network is “cloud”). The central controller SYS and/or the training system TSYS may be configured as a virtual system that is executed on a computer or a real computer-network or a virtual computer network (a technical term is “virtualization”).

The interface SYS.IF and/or the training interface TSYS.IF may be a hardware or software interface (e.g., a PCI bus, USB, or FireWire). The computing unit SYS.CU and/or the training computing unit TSYS.CU may include hardware and/or software components (e.g., a microprocessor or a field programmable gate array (FPGA). The memory unit SYS.MU and/or the training memory unit TSYS.MU may be configured as a random-access memory (RAM) or as permanent mass storage device (hard disk, USB stick, SD card, solid state disk (SSD)).

The interface SYS.IF and/or the training interface TSYS.IF may, for example, include a plurality of sub-interfaces that execute different method acts of the respective method according to the present embodiments. In other words, the interface SYS.IF and/or the training interface TSYS.IF may be configured as a plurality of interfaces SYS.IF and/or training interfaces TSYS.IF. The computing unit SYS.CU and/or the training computing unit TSYS.CU may, for example, include a plurality of sub-computing units that execute the different method acts of the respective method according to the present embodiments. In other words, the computing unit SYS.CU and/or the training computing unit TSYS.CU may be configured as a plurality of computing units SYS.CU and/or training computing units TSYS.CU.

FIG. 5 shows an example embodiment of a magnetic resonance imaging (MRI) system 1.

The MRI system 1 includes a magnetic resonance device 10. The magnetic resonance device 10 includes a scanner unit 11 formed by a magnet unit. In addition, the magnetic resonance device 10 has a patient receiving area 12 configured to receive a patient 13. In the present embodiment, the patient receiving area 12 is configured in a cylindrical shape and surrounded in a cylindrical shape in a circumferential direction by the scanner unit 11 (e.g., by the magnet unit). However, in principle, an embodiment of the patient receiving area 12 different therefrom may be provided at any time. The patient 13 may be pushed and/or moved into the patient receiving area 12 by a patient support device 14 of the MRI system 1. For this purpose, the patient support device 14 has a patient table 15 configured to be movable within the patient receiving area 12. For example, the patient table 15 is mounted so as to be movable in the direction of a longitudinal extension of the patient receiving area 12 and/or in the z-direction.

The patient receiving area 12 includes an enclosure 36 surrounding the patient receiving area 12 with an inner wall 37. In the present embodiment, the enclosure 36 surrounding the patient receiving area 12 is configured in one part with the radio-frequency antenna unit 20 (e.g., a side of the radio-frequency antenna unit 20 facing the patient receiving area 12). In an alternative embodiment, the enclosure 36 surrounding the patient receiving area 12 may also form a separate unit from the radio-frequency antenna unit 20.

The scanner unit 11 (e.g., the magnet unit) includes a superconducting main magnet 16 for generating a strong and, for example, constant main magnetic field 17. Further, the scanner unit 11 (e.g., the magnet unit) has a gradient coil unit 18 for generating magnetic field gradients that are used for spatial encoding during imaging. The gradient coil unit 18 is controlled by a gradient control unit 19 of the MRI system 1. The scanner unit 11 (e.g., the magnet unit) also includes a radio-frequency antenna unit 20 for exciting a polarization that is established in the main magnetic field 17 generated by the main magnet 16. The radio-frequency antenna unit or body coil 20 is controlled by a radio-frequency antenna control unit 21 of the MRI system 1 and radiates radio-frequency magnetic resonance sequences into the patient receiving area 12 of the magnetic resonance device 10.

To control the main magnet 16, the gradient control unit 19 and to control the radio-frequency antenna control unit 21, the MRI system 1 has a system control unit 22. The system control unit 22 is included by a computing unit of the MRI system 1. The system control unit 22 centrally controls the MRI system 1, such as, for example, for performing a predetermined imaging gradient echo sequence. In addition, the system control unit 22 includes an evaluation unit, not shown in detail, for evaluating medical image data or MRI image data that is captured during the magnetic resonance examination or examination.

Further, the MRI system 1 includes a user interface 23 that is connected to the system control unit 22. Control information such as, for example, imaging parameters, and reconstructed MRI image data may be displayed on a display unit 24 (e.g., on at least one monitor) of the user interface 23 for medical operating staff or medical staff. Further, the user interface 23 has an input unit 25, by which information and/or parameters may be entered by the medical operating staff during a scan.

The scanner unit 11 of the magnetic resonance device 10 is arranged together with the patient support device 14 within an MRI room 26. The system control unit 22 is arranged together with the user interface 23 within a control room 27. The control room 27 is configured separately from the MRI room 26. For example, the MRI room 26 is shielded from the control room 27 with respect to radio-frequency radiation. During an examination, the patient 13 is located within the MRI room 26, whereas the medical operating staff may be located within the control room 27. During preparatory positioning of the patient 13 on the patient table 15, the operating staff may be located in the MRI room 26. The MRI room 26 and the control room 27 in combination form the MRI examination room.

The MRI system 1 has a communication unit 28 for communication and/or information exchange between the patient 13 and the medical operating staff during an examination. On the operator side, the communication unit 28 has a communication element embodied as an operator console 29. The communication element (e.g., the operator console 28) may be arranged within the control room 27. The operator console 29 has an input element 30 and an output element 31. Herein, the input element 30 and/or the output element 31 may be configured as an acoustic and/or visual input element 30 and/or output element 31.

Further, on the patient side, the communication unit 28 has a first communication element embodied as an input element 32. The patient 13 may use the input element 32 to inform the operator (e.g., medical operating staff) of a condition, such as, for example, discomfort, during the examination. In the present embodiment, the input element 32 is configured as a patient call bell or alarm bell. However, in principle, further input elements 32 that appear advisable to the person skilled in the art, such as, for example, a microphone, etc., are possible in a further embodiments of the communication unit 28.

The MRI system 1 depicted may include further components usually included by MRI systems 1. A general mode of operation of an MRI system 1 is also known to the person skilled in the art so there will be no more detailed description of the further components.

Where not yet explicitly done, but advisable and in the spirit of the invention, individual embodiments, individual partial aspects, or features thereof may be combined with one another or interchanged without departing from the scope of the present invention. Where transferable, advantages of the invention described with reference to one example embodiment also apply to another example embodiment without being explicitly mentioned.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for ascertaining an optimal energy-saving state of a magnetic resonance imaging system, the method being computer-implemented and comprising:
receiving a set of rules with a central controller;
receiving at least one state of at least one component with the central controller, wherein the at least one component is a component of the magnetic resonance imaging system, an environment of the magnetic resonance imaging system, or the magnetic resonance imaging system and the environment of the magnetic resonance imaging system, and wherein the set of rules comprises at least one rule by which the optimal energy-saving state is determinable based on the at least one state of the at least one component;
determining the optimal energy-saving state based on the set of rules and the at least one state of the at least one component; and
providing information regarding the optimal energy-saving state.

2. The method of claim 1, further comprising setting the magnetic resonance imaging system to the optimal energy-saving state based on the provided information regarding the optimal energy-saving state.

3. The method of claim 1, wherein:
the method is initiated by a time trigger;
the method is initiated by a change in a state of the at least one state of the at least one component;
the method is initiated by receiving user input; or
any combination thereof.

4. The method of claim 1, wherein the at least one rule is adaptable in dependence on access authorization.

5. The method of claim 1, further comprising:
receiving optional user input regarding the optimal energy-saving state with the central controller,
wherein, when providing the information on the optimal energy-saving state, the information regarding the optimal energy-saving state provided by the user input is provided when user input has been received.

6. The method of claim 1, further comprising:
receiving time information with the central controller,
wherein the set of rules further comprises a rule relating to the time information, and
wherein the rule relating to the time information is taken into account when determining the optimal energy-saving state.

7. The method of claim 1, wherein the set of rules comprises a trained function, and
wherein, when determining the optimal energy-saving state, the trained function is applied to the at least one state of the at least one component, such that the optimal energy-saving state is determined.

8. The method of claim 1, wherein a component of the at least one component is a patient table, a computing system of the magnetic resonance imaging system, a planning system, an emergency entrance, or a magnetic resonance imaging examination room.

9. A method for providing a trained function, the method being computer-implemented and comprising:
receiving at least one state of at least one component;
receiving information regarding an optimal energy-saving state, wherein the information regarding the optimal energy-saving state depends on the at least one state of the at least one component;
training a function based on the at least one state of the at least one component and the information regarding the optimal energy-saving state; and
providing the trained function.

10. The method of claim 9, wherein the training is based on decentralized distributed training.

11. The method of claim 9, wherein the training takes place continuously during the execution of a method for ascertaining the optimal energy-saving state of the magnetic resonance imaging system, the method for ascertaining the optimal energy-saving state of the magnetic resonance imaging system comprising:
receiving a set of rules with a central controller;
receiving the at least one state of at the least one component with the central controller, wherein the at least one component is a component of the magnetic resonance imaging system, an environment of the magnetic resonance imaging system, or the magnetic resonance imaging system and the environment of the magnetic resonance imaging system, and wherein the set of rules comprises at least one rule by which the optimal energy-saving state is determinable based on the at least one state of the at least one component;
determining the optimal energy-saving state based on the set of rules and the at least one state of the at least one component; and
providing the information regarding the optimal energy-saving state,
wherein the received information regarding the optimal energy-saving state is the provided information regarding the optimal energy-saving state,
wherein the method further comprises:
receiving information about a degree with which the trained function is to be continuously further trained, and
wherein the degree is taken into account when training the function.

12. A central controller for ascertaining an optimal energy-saving state of a magnetic resonance imaging system, the central controller comprising:
an interface and a computing unit configured to:
receive a set of rules;
receive at least one state of at least one component, wherein the at least one component is a component of the magnetic resonance imaging system, an environment of the magnetic resonance imaging system, or the magnetic resonance imaging system and the environment of the magnetic resonance imaging system, wherein the set of rules comprises at least one rule by which an optimal energy-saving state is determinable based on the at least one state of the at least one component;
determine the optimal energy-saving state based on the set of rules and the at least one state of the at least one component; and
provide information regarding the optimal energy-saving state.

13. A magnetic resonance imaging system comprising:
a central controller for ascertaining an optimal energy-saving state of the magnetic resonance imaging system, the central controller comprising:
an interface and a computing unit configured to:
receive a set of rules;
receive at least one state of at least one component, wherein the at least one component is a component of the magnetic resonance imaging system, an environment of the magnetic resonance imaging system, or the magnetic resonance imaging system and the environment of the magnetic resonance imaging system, wherein the set of rules comprises at least one rule by which an optimal energy-saving state is determinable based on the at least one state of the at least one component;
determine the optimal energy-saving state based on the set of rules and the at least one state of the at least one component; and
provide information regarding the optimal energy-saving state.

14. In a non-transitory computer-readable storage medium that stores instructions executable by a central controller to ascertain an optimal energy-saving state of a magnetic resonance imaging system, the instructions comprising:
receiving a set of rules with a central controller;
receiving at least one state of at least one component with the central controller, wherein the at least one component is a component of the magnetic resonance imaging system, an environment of the magnetic resonance imaging system, or the magnetic resonance imaging system and the environment of the magnetic resonance imaging system, and wherein the set of rules comprises at least one rule by which the optimal energy-saving state is determinable based on the at least one state of the at least one component;
determining the optimal energy-saving state based on the set of rules and the at least one state of the at least one component; and
providing information regarding the optimal energy-saving state.

15. The non-transitory computer-readable storage medium of claim 14, wherein the instruction further comprise setting the magnetic resonance imaging system to the optimal energy-saving state based on the provided information regarding the optimal energy-saving state.

16. The non-transitory computer-readable storage medium of claim 14, wherein:
the method is initiated by a time trigger;
the method is initiated by a change in a state of the at least one state of the at least one component;
the method is initiated by receiving user input; or
any combination thereof.

17. The non-transitory computer-readable storage medium of claim 14, wherein the at least one rule is adaptable in dependence on access authorization.

18. The non-transitory computer-readable storage medium of claim 14, wherein the instructions further comprise:
receiving optional user input regarding the optimal energy-saving state with the central controller,
wherein, when providing the information on the optimal energy-saving state, the information regarding the optimal energy-saving state provided by the user input is provided when user input has been received.
